(19) United States
(12) Patent Application Publication
(10) Pub. No.: US 2006/0017471 A1
(43) Pub. Date: Jan. 26, 2006

(54) Phase detector

(75) Inventor: Nam Duc Nguyen, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Exar Corporation, Fremont, CA (US)

(21) Appl. No.: 10/896,372

(22) Filed: Jul. 20, 2004

(51) Int. Cl. G01R 25/00

(52) U.S. Cl. 327/3

(57) ABSTRACT

A phase detector is adapted to receive first and second signals and generate third and fourth signals representative of the difference between the phases of the first and second signals. The phase detector assert the third signal in response to the assertion of the first signal and unasserts the third signal in response to the assertion of the second signal. The phase detector asserts the fourth signal in response to the assertion of the third signal and unasserts the fourth signal in response to unassertion of the first signal. The phase detector may include combinatorial logic gates, thereby to generate the third and fourth signals in response to logic levels of the first and second signals. The phase detector may include sequential logic gates, thereby to generate the third and fourth signals in response to transitions of the first and second signals.

### FIELD OF THE INVENTION

The present invention relates to electronic circuits, and more particularly to phase detectors adapted to operate with return-to-zero (RZ) or pulse position modulation data in clock and data recovery system.

### BACKGROUND OF THE INVENTION

The increasing speed with which multiple types of data, such as text, audio and video, are transported over existing communication networks has brought to the fore the reliability with which such data transportation is carried out. In accordance with one conventional method, to ensure reliable data transfer, the data is first encoded with a reference clock signal at the transmitting end of the network to generate a composite signal. Thereafter, the composite signal is transmitted over the network to the receiving end. At the receiving end, the data and clock signals are recovered from the composite signal to ensure that the data and clock signals remain synchronous with respect to each other.

The clock and data recovery is typically carried out, for example, by a phase locked loop. In operation, a phase locked loop maintains a fixed relationship between the phase and frequency of the signal it receives and those of the signal it generates. A phase-locked loop often includes a phase detector that receives a pair of signals, and in response, generates a pair of output signals representative of the difference between the phases of the two received signals.

One widely known phase detector, referred to as Hogge phase detector, and which can only rely on the non-return to zero (NRZ) or pulse width modulation (PWM) property of data to re-time the input data at the optimal sampling point is shown in FIG. 1. Phase detector (PD) 50 requires that the duty cycle distortion of the recovered clock be kept at minimum. Also, when signals P_UP or P_DN are active, additional jitter is created in PD 50. It is also well known that the gain of the phase-locked loop (not shown) in which PD 50 is disposed is dependent on the bandwidth of the read data and which is desired to be kept relatively narrow. The operation of PD 50 is described further below.

A timing diagram with the clock aligned nearly perfectly to the input data transitions is shown in FIG. 2 for an NRZ data stream. The input NRZ signal is provided to PD 50 on data signal line labeled Rdata, which is applied to the input terminal D of flip-flop 12. The output QN of flip-flop 12 is supplied to the input terminal D of flip-flop 14.

Clock signal Rclk is applied to the input clock terminal of flip-flop 12, and the inverse of clock signal Rclk is applied to the input clock terminal of flip-flop 14. The input and output of the flip-flop 12 are provided to an exclusive-OR gate 24 to provide signal P_UP signal. The input and output of the flip-flop 14 are provided to a second exclusive-OR gate 26, to provide signal P_DN. Signals P_UP and P_DN are provided to a charge pump (not shown).

As can be seen from the block diagram of FIG. 1 and the timing diagram of FIG. 2, the P_UP pulses are generated during the time interval between data transitions and the next rising edge of the clock. Every P_UP pulse generates a P_DN pulse with a fixed width of half of the clock period. Ideally the width of the P_UP and P_DN pulses should be equal to half of the clock period. When the clock leads or lags from this ideal position, the P_UP pulse becomes smaller or larger than the P_DN pulse, respectively. The P_UP and P_DN pulses are fed to the charge pump and loop filter which are part of a phase-locked loop (PLL) (not shown). The difference between the pulse width of the signals P_UP and P_DN is the feedback signal in the PLL.

When the clock is aligned nearly perfectly to the input data transitions, the difference between the pulse widths of P_UP and P_DN is equal to nearly zero, and the PLL is in a phase-locked condition. It is seen that the sampling point of the data is optimal since the sampling (rising) edge of the clock is located near the center of the data, thus providing the maximum noise margin. Referring to FIG. 2, it is seen that each NRZ of data RDATA pulse provides two P_UP signals and two P_DN signals, resulting in two ramp-up and ramp-down transitions of the loop filter voltage, as shown at the bottom of FIG. 2.

FIG. 3 illustrates what happens if RZ type data is used for the input RDATA signal shown at the top of FIG. 3. As can be seen, since the clock rising edge 32 is aligned with the falling edge 34 of the RZ data, a misalignment may result in the one pulse not being sampled. Accordingly, PD 50 is very susceptible to noise for RZ data and is also not suitable for Pulse Position Modulation (PPM) data format used in the magnetic recording technology or the communication technology.

FIG. 4 is a simplified block diagram of a tri-wave phase detector 100, as known in the prior art. Tri-wave phase detector 100 is shown as including three flip-flops and three XOR gates. Tri-wave detector 100 provides a reduced sensitivity to data transition density. However, tri-wave detector 100 is more sensitive to duty cycle distortion in the clock signal than is Hogge's phase detector.

FIG. 5 is a simplified block diagram of a modified tri-wave phase detector 150, as known in the prior art. Modified tri-wave phase detector 150 uses two distinct down-integration intervals clocked on opposite edges of the clock, rather than a single down-integration of twice the strength clocked on a single edge. This enables tri-wave phase detector 150 to have relatively improved duty cycle performance compared to tri-wave phase detector 100. However, both tri-wave phase detector 100 as well as modified tri-wave phase detector 150 suffer from unacceptable levels of jitter. Moreover, the center offsets of both these detectors are dependent on the duty cycle of the clock signal CLK as well as the transient voltage at the output terminals of relevant flip-flops during the active cycle of the phase detector. U.S. Pat. Nos. 6,324,236 and 5,027,085 also describe examples of different circuits adapted to detect the phase of a RZ data signal.

### BRIEF SUMMARY OF THE INVENTION

A phase detector in accordance with the present invention receives first and second signals and, in response, generates third and fourth signals representative of the difference between the phases of the first and second signals. The phase detector assert the third signal in response to the assertion of the first signal and unasserts the third signal in response to the assertion of the second signal. The phase detector asserts the fourth signal in response to the assertion of the second signal and unasserts the fourth signal in response to unassertion of the first signal. The first and second signals represents data and clock signals.

In some embodiments, the phase detector includes combinatorial logic gates, such as AND gates. In these embodiments, the phase detector generates the third and fourth signals in response to logic levels of the first and second signals. In some embodiments, the phase detector includes a first combinatorial logic gate adapted to receive the first and second signals and generate the third signal, and a second combinatorial logic gate adapted to receive the first signal and an inverse of the second signal and generate the fourth signal. Each of the first and second logic gates may be an AND gate further adapted to receive an enabling signal.

In some embodiments, the phase detector includes, in part, sequential logic gates, such as flip-flops gates. In these embodiments, the phase detector generates the third and fourth signals in response to transitions of the first and second signals. In some embodiments, the phase detector includes a first combinatorial logic gate adapted to receive the first signal and generate a fifth signal, a first sequential logic gate adapted to receive the fifth signal at its clock input terminal and to generate the third signal, a second combinatorial logic gate adapted to receive the second signal and an output signal of the first sequential logic gate and to generate a sixth signal, and a second sequential logic gate adapted to receive the sixth signal at its clock input terminal and to generate the fourth signal. The first sequential logic gate is reset in response to the second signal, and the second sequential logic gate is reset in response to the first signal.

### BRIEF DESCRIPTION OF THE DRAWINGS

FIG. 1 is a simplified block diagram of a phase detector, as known in the prior art.

FIG. 2 is a timing diagram of various signals as the phase detector of FIG. 1 receives NRZ data or PWM data.

FIG. 3 is a timing diagram of various signals as the phase detector of FIG. 1 receives RZ data.

FIGS. 4 and 5 show tri-wave phase detectors, as known in the prior art.

FIG. 6 shows a phase detector, in accordance with one exemplary embodiment of the present invention.

FIG. 7 shows an exemplary timing diagram of signals associated with the phase detector of FIG. 6.

FIG. 8 shows a phase detector, in accordance with another exemplary embodiment of the present invention.

FIG. 9 shows an exemplary timing diagram of signals associated with the phase detector of FIG. 8.

FIG. 10 shows an exemplary timing diagram of signals associated with the phase detector of FIG. 8.

### DETAILED DESCRIPTION OF THE INVENTION

FIG. 6 is a schematic diagram of a phase detector 200 adapted to detect the phase of data signal Rdata relative to the phase of signal Rclk, in accordance with one exemplary embodiment of the present invention. Phase detector 200 is shown as including combinatorial logic gates, namely AND gates 202, 204 and inverter 206. Signal Rdata is applied to input terminals of both AND gates 202, and 204. Signal Rclk is applied to an input terminal of AND gate 204. Inverse of signal Rclk is applied to an input terminal of AND gate 202. Signal Enable is also applied to an input terminal of each AND gates 202, and 204. AND gate 202 generates output signal P_UP, and AND gate 204 generates output signal P_DN. Signals P_UP an P_DN are generated in response to the logic levels of signals Rdata and Rclk.

Signal Enable is used to enable or to disable phase detector 200. Accordingly, when signal Enable is, e.g., in a logic high state, phase detector 200 is enabled, and when signal Enable is, e.g., in a logic low state, phase detector 200 is disabled.

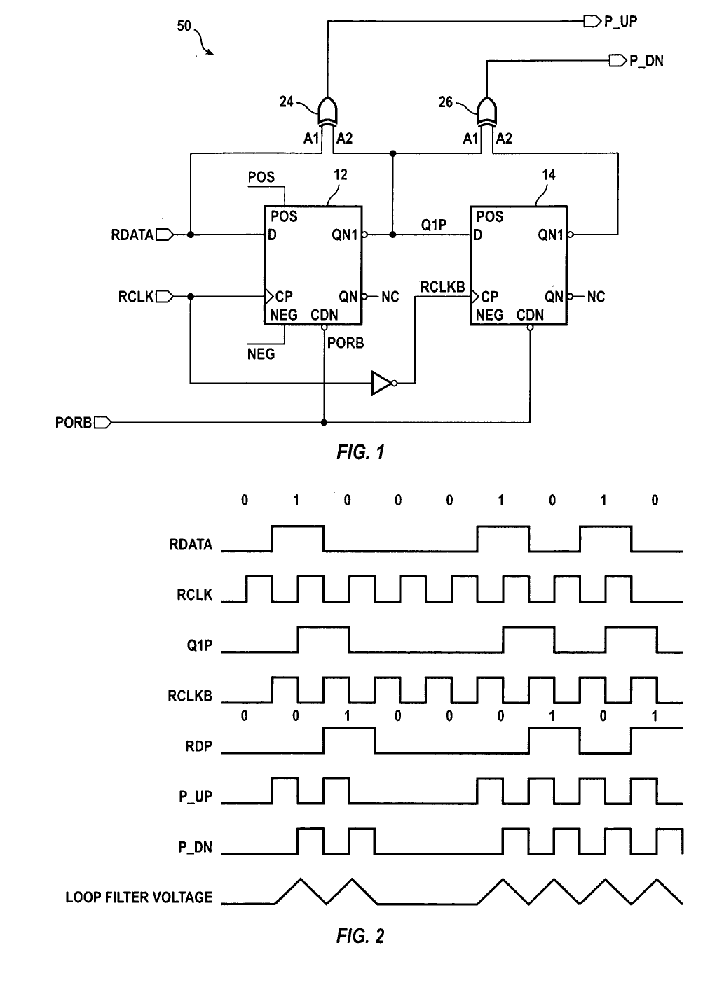

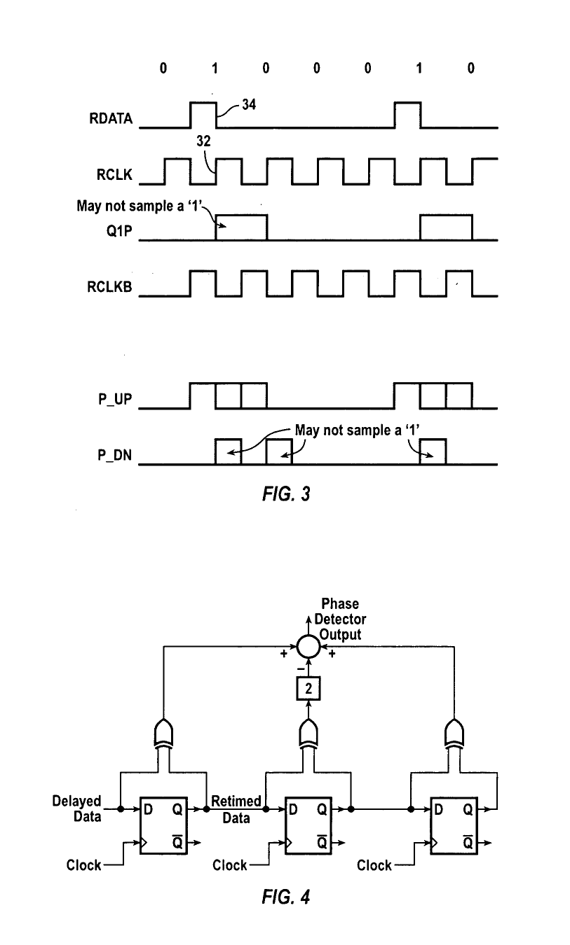

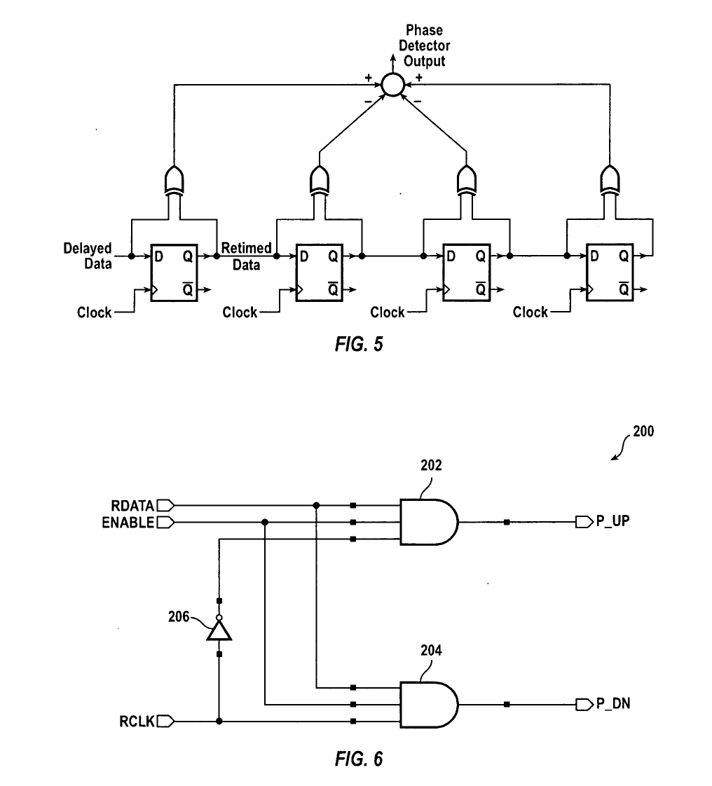

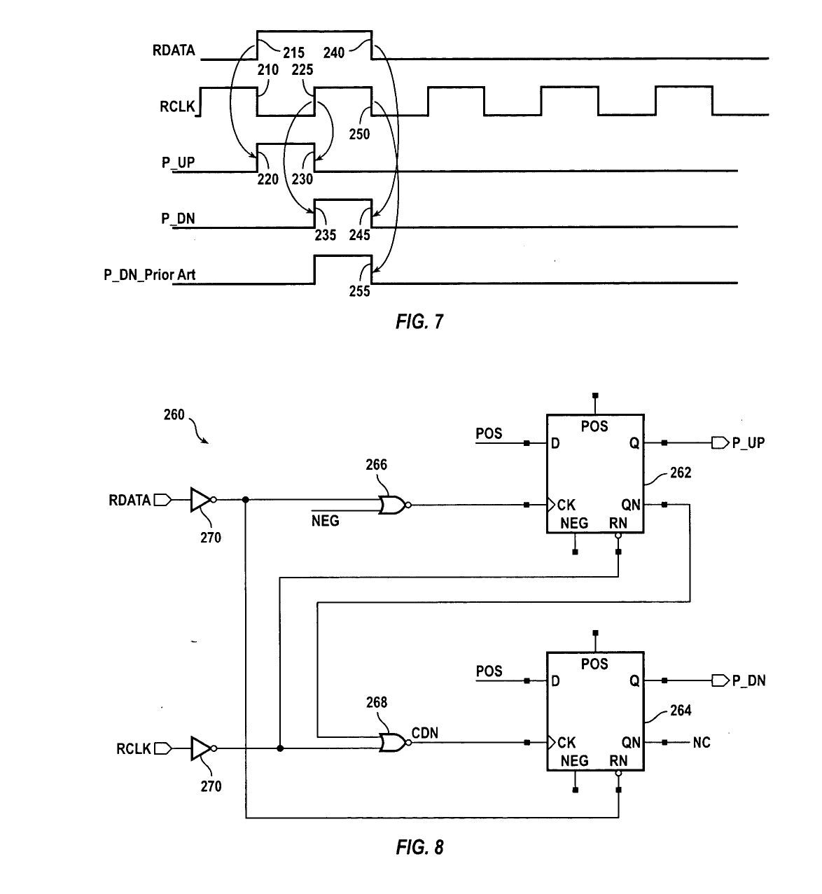

FIG. 7 shows a timing diagram of some of the signals received by or generated by phase detector 200, when signals Rdata and Rclk are in-lock, in accordance with one exemplary embodiment. As seen from this timing diagram, assuming clock signal Rclk is in a logic low state (e.g., due to high-to-low transition 210) after signal Rdata transitions to a high logic state (becomes high) 215, signal P_UP also goes high 220. Thereafter, when signal Rclk goes high 225, signal P_UP goes low 230, and signal P_DN goes high 235. Signal P_DN remains high until signal Rdata goes low 240, thereby causing signal P_DN to go low 245. In conventional Hogge type phase detectors, such as that shown in FIG. 1, the high-to-low transition 255 of a signal corresponding to signal P_DN (shown in FIG. 7 as signal P_DN_PriorArt) occurs in response to high-to-low transition 250 of signal Rclk. However, in accordance with the present invention, the high-to-low transition 245 of signal P_DN occurs in response to high-to-low transition 240 of signal Rdata.

FIG. 8 is a schematic diagram of a phase detector 260 adapted to detect the phase of data signal Rdata relative to the phase of signal Rclk, in accordance with another exemplary embodiment of the present invention. Phase detector 260 is shown as including sequential logic gates, namely flip-flops 262, 264, as well as combinatorial logic gates, namely NOR gates 266, 268, and inverters 270 and 272. Signal Rdata is applied to inverter 270 whose output drives one of the input terminals of NOR gate 266. Signal Rdata is also applied to the asynchronous reset terminal RN of flip-flop 264. The other input terminal of NOR gate 266 receives an enabling/disabling signal Disable. The output terminal of NOR gate 266 is applied to the clock input terminal CK of flip-flop 262. The data input terminal of flip-flop 262 is coupled to node Pos. Signal Rclk is applied to inverter 272 whose output terminal drives one of the input terminals of NOR gate 268. The other input terminal of NOR gate 268 is coupled to QN output terminal of flip-flop 262. The output terminal of NOR gate 268 is applied to the clock input terminal CK of flip-flop 264. The data input terminal of flip-flop 264 is coupled to node Pos. The Q output terminals of flip-flops 262 and 264 respectively generate signals P_UP and P-DN. Node Pos receives a positive voltage supply and node Neg receives negative voltage supply. The output terminal of inverter 272 is also applied to the asynchronous reset terminal RN of flip-flop 262. Signals P_UP an P_DN are generated in response to the transitions of signals Rdata and Rclk.

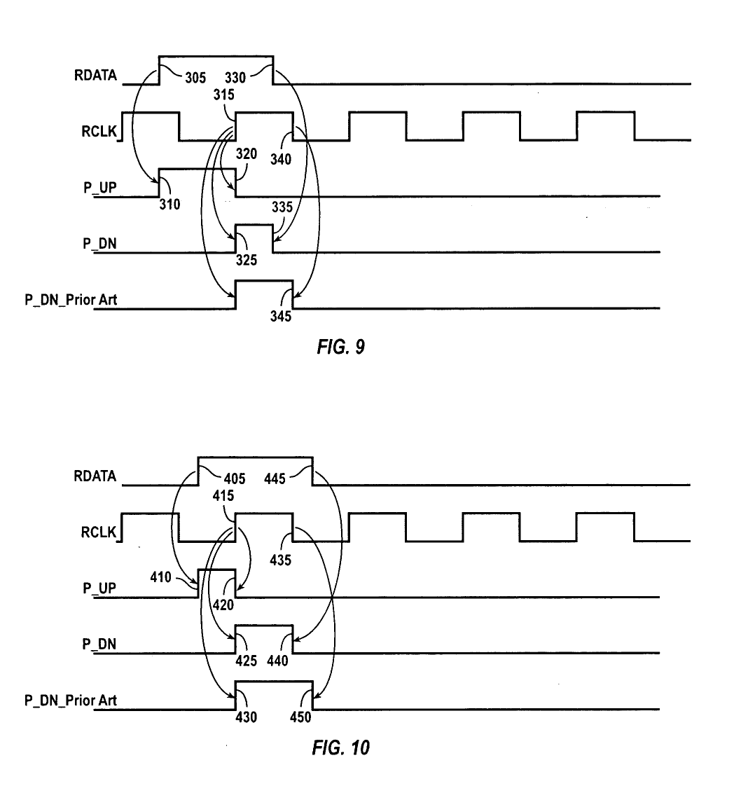

FIG. 9 shows an exemplary timing diagram of some of the signals received by or generated by phase detector 260, when signal Rdata lead signals and Rclk. As seen from this timing diagram, when signal Rdata goes high 305, signal P_UP also goes high 310. Signal P_UP remains high until signal Rclk goes high 315 to reset flip-flop 262, thereby causing signal P_UP to go low 320. Also, in response to the low-to-high transition 315 of signal Rclk, signal P_DN makes a low-to-high transition 325. Signal P_DN remains in a high states until signal RDATA goes from high to low 330 to reset flip-flop 264, thereby causing signal P_DN to go low 335. In conventional Hogge type phase detectors, such as that shown in FIG. 1, the high-to-low transition 345 of a signal corresponding to signal P_DN (shown in FIG. 8 as signal P_DN_PriorArt) occurs in response to a high-to-low transition 340 of signal Rclk. However, in accordance with the present invention, the high-to-low transition 335 of signal P_DN occurs in response to high-to-low transition 330 of signal Rdata.

FIG. 10 shows another exemplary timing diagram of some of the signals received by or generated by phase detector 260, when signals Rdata lags signals and Rclk. As seen from this timing diagram, when signal Rdata goes high 405, signal P_UP also goes high 410. Signal P_UP remains high until signal Rclk makes a low-to-high transition 415 to reset flip-flop 262, thereby causing signal P_UP to go low 420. Also, in response to the low-to-high transition 415 of signal Rclk, signal P_DN makes a low-to-high transition 425. Signal P_DN remains in a high states until signal Rdata goes from high to low 445, at which point signal P_DN goes low 440. In conventional Hogge type phase detectors, such as that shown in FIG. 1, the high-to-low transition 450 of a signal corresponding to signal P_DN (shown in FIG. 10 as signal P_DN_PriorArt) occurs in response to high-to-low transition 435 of signal Rclk. However, in accordance with the present invention, the high-to-low transition 440 of signal P_DN occurs in response to high-to-low transition 445 of signal Rdata.

Unlike the prior art phase detectors which cause signal P_DN to become inactive when signal Rclk becomes inactive (e.g., when signal Rclk transitions from high to low), a phase detector in accordance with the present invention, causes signal P_DN to become inactive (e.g., from active high to inactive low) in response to transitions (e.g. from active high to inactive low level) of data signal Rdata. Accordingly, a phase detector in accordance with the present invention, causes transitions from the inactive levels (e.g., low) to the active levels (e.g., high) of signal Rclk to be positioned nearly at the center of the transitions of signal Rdata for RZ or pulse-position modulation data. Accordingly, a phase detector in accordance with the present invention, is immune to dependency of the duty cycle of the received clock signal and thus is adapted to restore the 50% duty cycle of the clock. Furthermore, a phase detector in accordance with the present invention, also suppresses the unnecessary active cycles of the phase detector by utilizing the sample and hold circuit after the filter of the phase lock loop (PLL) and hence the bandwidth of the read data is kept at minimum.

The above embodiments of the present invention are illustrative and not limitative. The invention is not limited by any particular arrangement of logic gates used to generate the phase signals. The invention is not limited by the logic level which defines whether a signal is active or inactive. Thus, in some embodiments, a high logic level may be an active level while in other embodiments, a low logic level may be an active level. The invention is not limited by any particular combinatorial or sequential logic. Other additions, subtractions or modification are obvious in view of the present invention and are intended to fall within the scope of the appended claims.

What is claimed is:

1. A phase detector comprising:
circuitry adapted to receive first and second signals each having a phase; wherein said circuitry is adapted to generate a third signal that is asserted in response to the first signal being asserted and which is unasserted in response to the second signal being asserted; and wherein said circuitry is further adapted to generate a fourth signal that is asserted in response to the second signal being asserted and which is unasserted in response to the first signal being unasserted.

2. The phase detector of claim 1 wherein the first signal represents a data signal and wherein the second signal represents a clock signal.

3. The phase detector of claim 1 wherein said phase detector generates the third and fourth signals in response to logic levels of the first and second signals.

4. The phase detector of claim 3 wherein said phase detector further comprises:
a first combinatorial logic gate adapted to receive the first and second signals and generate the third signal;
a second combinatorial logic gate adapted to receive the first signal and an inverse of the second signal and generate the fourth signal.

5. The phase detector of claim 4 wherein each of said first and second logic gates is adapted to receive an enabling signal.

6. The phase detector of claim 4 wherein each of said first and second logic gates is an AND gate.

7. The phase detector of claim 1 wherein said phase detector generates the third and fourth signals in response to transitions of the first and second signals.

8. The phase detector of claim 3 wherein said phase detector further comprises:
a first combinatorial logic gate adapted to receive the first signal and generate a fifth signal;
a first sequential logic gate adapted to receive the fifth signal at its clock input terminal and to generate the third signal;
a second combinatorial logic gate adapted to receive the second signal and an output signal of the first sequential logic gate and to generate a sixth signal;
a second sequential logic gate adapted to receive the sixth signal at its clock input terminal and to generate the fourth signal.

9. The phase detector of claim 8 wherein said first sequential logic gate is reset in response to the second signal.

10. The phase detector of claim 9 wherein said second sequential logic gate is reset in response to the first signal.

11. The phase detector of claim 10 wherein each of said first and second sequential logic gates is a flip-flop with a data input terminal that is coupled to a positive supply voltage.

12. A method of detecting a phase difference, the method comprising:
receiving first and second signals;
asserting the first signal;
asserting a third signal in response to the assertion of the first signal;
asserting the second signal;
unasserting the third signal in response to the assertion of the second signal;
asserting a fourth signal in response to the assertion of the second signal;
unasserting the first signal; and
unasserting the fourth signal in response the unassertion of the first signal.

13. The method of claim 12 wherein the first signal represents a data signal and wherein the second signal represents a clock signal.

14. The method of claim 12 wherein said third signal is asserted in response to a logic level of the first signal.

15. The method of claim 13 wherein said third signal is unasserted in response to a logic level of the second signal.

16. The method of claim 15 wherein said fourth signal is asserted in response to a logic level of the second signal.

17. The method of claim 16 wherein said fourth signal is unasserted in response to a logic level of the first signal.

18. The method of claim 12 wherein said third signal is asserted in response to a transition of the first signal.

19. The method of claim 18 wherein said third signal is unasserted in response to a transition of the second signal.

20. The method of claim 19 wherein said fourth signal is asserted in response to a transition of the second signal.

21. The method of claim 20 wherein said fourth signal is unasserted in response to a transition of the first signal.
